(19) United States
(12) Patent Application Publication
(10) Pub. No.: US 2015/0091911 A1
(43) Pub. Date: Apr. 2, 2015

(54) MOVABLE MEMS ELEMENT WITH STICTION MITIGATING SPRING

(71) Applicant: PIXTRONIX, INC., San Diego, CA (US)

(72) Inventor: Wilhelmus A. de Groot, Palo Alto, CA (US)

(73) Assignee: PIXTRONIX, INC., San Diego, CA (US)

(21) Appl. No.: 14/149,231

(22) Filed: Jan. 7, 2014

Related U.S. Application Data
(60) Provisional application No. 61/884,567, filed on Sep. 30, 2013.

(51) Int. Cl. G02B 26/02; H02N 1/00; H01L 21/02; G06F 3/01; G09G 5/00; B81B 5/00; G06T 1/00

(52) U.S. Cl. CPC G02B 26/02; B81B 5/00; H02N 1/006; G06T 1/00; G06F 3/01; G09G 5/00; H01L 21/02
USPC 345/501; 359/230; 310/300; 29/25.02

(57) ABSTRACT

Systems, methods and methods of manufacture for, among other things, a MEMS device may be provided with a pair of electrodes that are separated by a gap. At least one of the electrodes is movable toward the other electrode. The MEMS device may include a beam that is positioned within the gap and arranged between the electrodes. As the movable electrode moves toward the other electrode, a portion of the MEMS device also moves towards, comes into contact with, and deflects the beam. As the beam deflects, it applies a force upon the MEMS device that opposes the movement of electrode toward the other electrode.

### REFERENCE TO RELATED APPLICATION

This claims the benefit of U.S. Provisional Patent Application No. 61/884,567, filed Sep. 30, 2013, which is incorporated by reference herein in its entirety.

### TECHNICAL FIELD

This disclosure relates to the field of displays, and particularly to displays with movable electromechanical system elements and methods for manufacturing the same.

### DESCRIPTION OF THE RELATED TECHNOLOGY

Electromechanical systems (EMS) include devices having electrical and mechanical elements, actuators, transducers, sensors, optical components such as mirrors and optical films, and electronics. EMS devices or elements can be manufactured at a variety of scales including, but not limited to, microscales and nanoscales. For example, microelectromechanical systems (MEMS) devices can include structures having sizes ranging from about a micron to hundreds of microns or more. Nanoelectromechanical systems (NEMS) devices can include structures having sizes smaller than a micron including, for example, sizes smaller than several hundred nanometers. Electromechanical elements may be created using deposition, etching, lithography, and/or other micromachining processes that etch away parts of substrates and/or deposited material layers, or that add layers to form electrical and electromechanical devices.

MEMS display devices are known in the art, and like all MEMS devices, stiction can be a problem. Stiction arises when two MEMS surfaces move into contact, and subsequently stick together so that they cannot move apart, or at least not easily move apart. Stiction can cause MEMS devices to fail or work poorly. One technique for reducing stiction is described in U.S. Pat. No. 7,859,740. As disclosed therein, two planar MEMS surfaces are brought into contact during device operation. Stiction may bind these planar surfaces together. To reduce the likelihood of binding by stiction, an opening is formed within at least one planar MEMS surface. The opening is formed by cutting into the surface and bending away from the surface enough material to form the opening. The material that is bent away provides a deflecting body on the MEMS surface. When the MEMS surface is moved into contact with the other MEMS surface, the other MEMS surface pushes against and deforms the deflecting body. The deformed deflecting body creates a resisting force that tends to push the MEMS surfaces apart and helps reduce stiction. Although these systems can work well, it would be beneficial to the art to have stiction reducing systems that do not cut through MEMS surfaces or form protrusions on planar surfaces.

### SUMMARY

The systems, methods and devices of this disclosure each have several innovative aspects, no single one of which is solely responsible for the desirable attributes disclosed herein.

One innovative aspect of the subject matter described in this disclosure can be implemented in a microelectromechanical system (MEMS) device having a first electrode, a second electrode adjacent the first electrode and defining a gap between the first and the second electrode and being capable of moving across the gap and toward the first electrode in response to a voltage difference between the first and the second electrode, and a beam positioned away from the gap between the first and second electrode and being capable of deflecting in response to the second electrode moving toward the first electrode and thereby apply a force that opposes movement of the second electrode toward the first electrode. In some implementations, the MEMS device may further include an element extending from the second electrode and arranged to contact the beam as the second electrode moves toward the first electrode. In some implementations, the element extending from the second electrode includes a shutter.

In some implementations, the MEMS device has a beam that includes a beam electrode and the element includes an element electrode capable of moving toward the beam electrode responsive to a voltage difference between the beam electrode and the element electrode.

In some implementations of the MEMS device, the beam has a first and second end and the first end attaches to an anchor and the second end is free to move. Optionally, the beam has an accurate shape. In some implementations at least part of the beam is made from an elastic material for elastically deflecting to store energy for driving the second electrode away from the first electrode.

In some implementations the beam deflects in accord with a spring force and the spring force is selected to prevent the second electrode from contacting the first electrode.

In some implementations, the second electrode and the beam electrode are electrically connected to be at a substantially same voltage. In other implementations the first electrode and the beam electrode are electrically connected to be at a substantially same voltage.

In some implementations the MEMS device includes a controller for applying a first voltage difference between the first electrode and the second electrode and for applying a second different voltage difference between the beam electrode and the second electrode.

In some implementations, the MEMS device has a beam that includes an element to limit deflection of the beam to prevent the second electrode from moving into contact with the first electrode.

In some implementations the MEMS device further includes a display, a processor that is configured to communicate with the display, the processor being configured to process image data and a memory device that is configured to communicate with the processor. Optionally, the device may include a driver circuit configured to send at least one signal to the display and a controller configured to send at least a portion of the image data to the driver circuit. Further optionally, the device may include an image source module configured to send the image data to the processor, wherein the image source module includes at least one of a receiver, transceiver, and transmitter. Still further, the device may optionally include an input device configured to receive input data and to communicate the input data to the processor.

Another innovative aspect of the subject matter described in this disclosure can be implemented in a method for manufacturing a microelectromechanical system (MEMS) device, including providing an electrode pair having a first electrode and a second electrode adjacent the first electrode to define a gap between the first and the second electrode, and arranging the second electrode to be capable of moving across the gap and toward the first electrode in response to a voltage difference between the first and the second electrode, and providing a beam positioned away from the gap and being capable of deflecting in response to the second electrode moving toward the first electrode to apply a force that opposes movement of the second electrode toward the first electrode.

In some implementations, the method arranges the second electrode to couple the second electrode to a spring formed on a substrate and being capable of deflecting to allow the second electrode to move across the gap.

In some implementations the method provides an element, which in some implementations may be a shutter, for extending from the second electrode and arranged to contact the beam as the second electrode moves toward the first electrode.

In some implementations the method also includes forming a beam electrode on the beam, and forming an element electrode on the element. In some implementations, the method includes forming an anchor on a substrate and securing an end of the beam to the anchor. In some other implementations, the method includes forming a different end of the beam as an arm suspended over the substrate.

In some implementations, the method includes forming the beam of an elastic material for having the beam elastically deflect to store energy for driving the second electrode away from the first electrode. In some implementations, the method includes selecting a width of the beam to provide a spring force selected to prevent the second electrode from contacting the first electrode. In some implementations, the method includes forming an electrical interconnect between the second electrode and the beam electrode and may include forming an electrical interconnect between the first electrode and the beam electrode.

In some implementations, the method includes providing a controller for applying a first voltage difference between the first electrode and the second electrode and for applying a second different voltage difference between the beam electrode and the second electrode. In some implementations, the method includes forming an element proximate the beam to limit deflection of the beam to prevent the second electrode from moving into contact with the first electrode.

Details of one or more implementations of the subject matter described in this disclosure are set forth in the accompanying drawings and the description below. Although the examples provided in this disclosure are primarily described in terms of EMS and MEMS-based displays the concepts provided herein may apply to other types of displays such as liquid crystal displays (LCDs), organic light-emitting diode (“OLED”) displays, and field emission displays. Other features, aspects, and advantages will become apparent from the description, the drawings and the claims. Note that the relative dimensions of the following figures may not be drawn to scale.

### BRIEF DESCRIPTION OF THE DRAWINGS

FIG. 1A is an example of a display apparatus having MEMS elements.

FIG. 1B is a block diagram of the display apparatus of FIG. 1A.

FIG. 2A depicts in more detail a light modulator of the type depicted in FIG. 1A.

FIG. 2B depicts an alternate implementation of a light modulator of the type depicted in FIG. 1A.

FIG. 3 is an actuator having deformable beams.

FIGS. 4A and 4B depict in more detail the action of the beam in opposing movement caused by the electrode pair.

FIG. 5 is a graph illustrating the spring force of one implementation of a beam.

FIGS. 6A, 6B and 6C are a MEMS device having a deflecting beam with an electrode.

FIG. 7 is an alternate implementation having a mechanical stop.

FIGS. 8A and 8B illustrate certain implementations having deformable beams acting on a spring.

FIGS. 9A and 9B are system block diagrams illustrating a display device that includes a plurality of shutter display elements.

Like reference numbers and designations in the various drawings indicate like elements.

### DETAILED DESCRIPTION

The following description is directed to certain implementations for the purposes of describing the innovative aspects of this disclosure. However, a person having ordinary skill in the art will readily recognize that the teachings herein can be applied in a multitude of different ways. The described implementations may be implemented in any device, apparatus, or system including those that can be configured to display an image, whether in motion (such as video) or stationary (such as still images), and whether textual, graphical or pictorial. More particularly, it is contemplated that the described implementations may be included in or associated with a variety of electronic devices such as, but not limited to: mobile telephones, multimedia Internet enabled cellular telephones, mobile television receivers, wireless devices, smartphones, Bluetooth® devices, personal data assistants (PDAs), wireless electronic mail receivers, hand-held or portable computers, netbooks, notebooks, smartbooks, tablets, printers, copiers, scanners, facsimile devices, global positioning system (GPS) receivers/navigators, cameras, digital media players (such as MP3 players), camcorders, game consoles, wrist watches, clocks, calculators, television monitors, flat panel displays, electronic reading devices (e.g., e-readers), computer monitors, auto displays (including odometer and speedometer displays, etc.), cockpit controls and/or displays, camera view displays (such as the display of a rear view camera in a vehicle), electronic photographs, electronic billboards or signs, projectors, architectural structures, microwaves, refrigerators, stereo systems, cassette recorders or players, DVD players, CD players, VCRs, radios, portable memory chips, washers, dryers, washer/dryers, parking meters, packaging (such as in electromechanical systems (EMS) applications including micro electromechanical systems (MEMS) applications, as well as non-EMS applications), aesthetic structures (such as display of images on a piece of jewelry or clothing) and a variety of EMS devices. The teachings herein also can be used in non-display applications such as, but not limited to, electronic switching devices, radio frequency filters, sensors, accelerometers, gyroscopes, motion-sensing devices, magnetometers, inertial components for consumer electronics, parts of consumer electronics products, varactors, liquid crystal devices, electrophoretic devices, drive schemes, manufacturing processes and electronic test equipment. Moreover, the teachings herein may be used in many applications that include MEMS devices that have components that come into contact during operation. Thus, the teachings are not intended to be limited to the implementations depicted solely in the Figures, but instead have wide applicability as will be readily apparent to one having ordinary skill in the art.

In certain implementations described herein, a MEMS device may be provided with a pair of electrodes that are separated by a gap. At least one of the electrodes is movable toward the other electrode. The MEMS device may include a beam that is positioned within the gap and arranged between the electrodes. As the movable electrode moves toward the other electrode, a portion of the MEMS device also moves towards, comes into contact with, and deflects the beam. As the beam deflects, it applies a force upon the MEMS device that opposes the movement of electrode toward the other electrode. The force applied by the beam may prevent the movable electrode from contacting the other electrode and, if contact is made, may provide a force that will reduce the effects of stiction by providing a force that tends to drive the electrodes apart.

In certain implementations, the beam may be a cantilevered beam that is disposed proximate an element, such as a shutter or other element, that is being moved by the action of the electrodes moving together. The cantilevered beam can have a free end and a fixed end. The free end of the beam may contact the shutter or the other moving element as it is being pulled by the action of the movable electrode. The cantilevered beam can made of an elastic material which allows the free end of the beam to move while the fixed end stays secured in place. The free end of the beam can move as the shutter or other moving element pushes against it. As the free end moves, the beam elastically deforms to generate a spring force that opposes the motion of the shutter or the other moving element. The elastically deformed beam stores energy that can be released to push the shutter or the other moving element in a direction that drives the movable electrode away from the other electrode.

In certain implementations, the beam includes an electrode and the moving element, such as the shutter, also includes an electrode. The electrode on the beam, otherwise referred to as the beam electrode, faces the electrode on the moving element. A voltage difference applied across the beam electrode and the electrode on the moving element causes the moving element to move toward the beam.

In certain implementations, a controller applies a voltage difference across the pair of electrodes separated by a gap and a voltage difference across the beam electrode and the electrode on the moving element. The controller can control the voltage differences between the electrodes to apply a first voltage difference between the beam electrode and the electrode on the moving element and a second larger voltage difference between the pair of electrodes separated by the gap. This allows the controller to set up a voltage gradient across multiple electrodes, which can allow the moving element to be driven in stages.

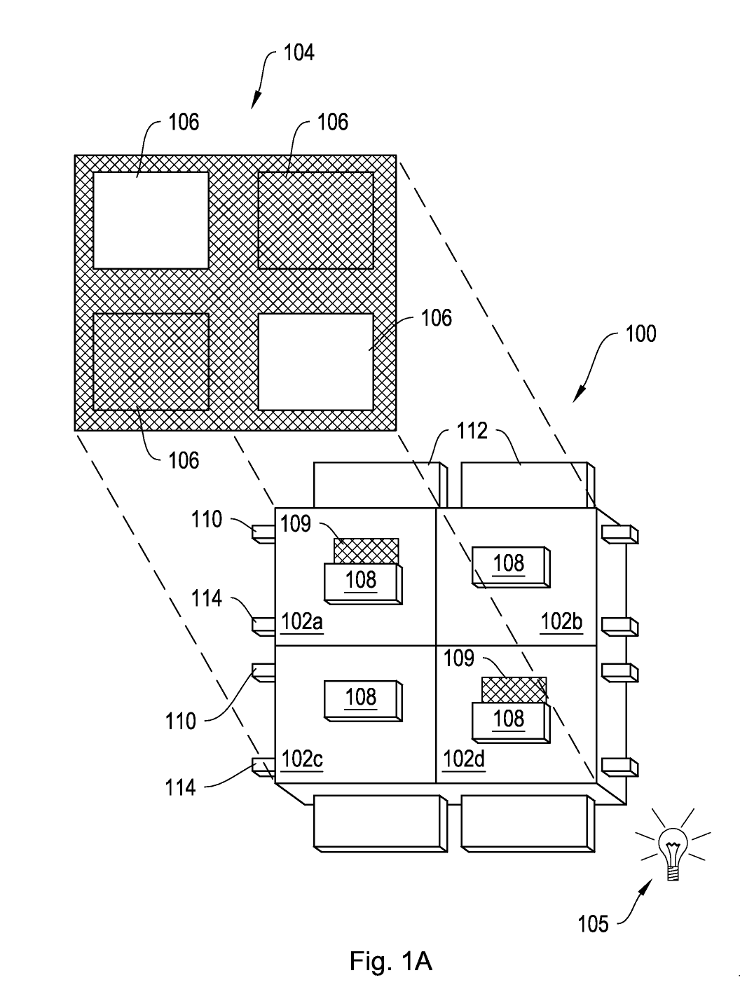

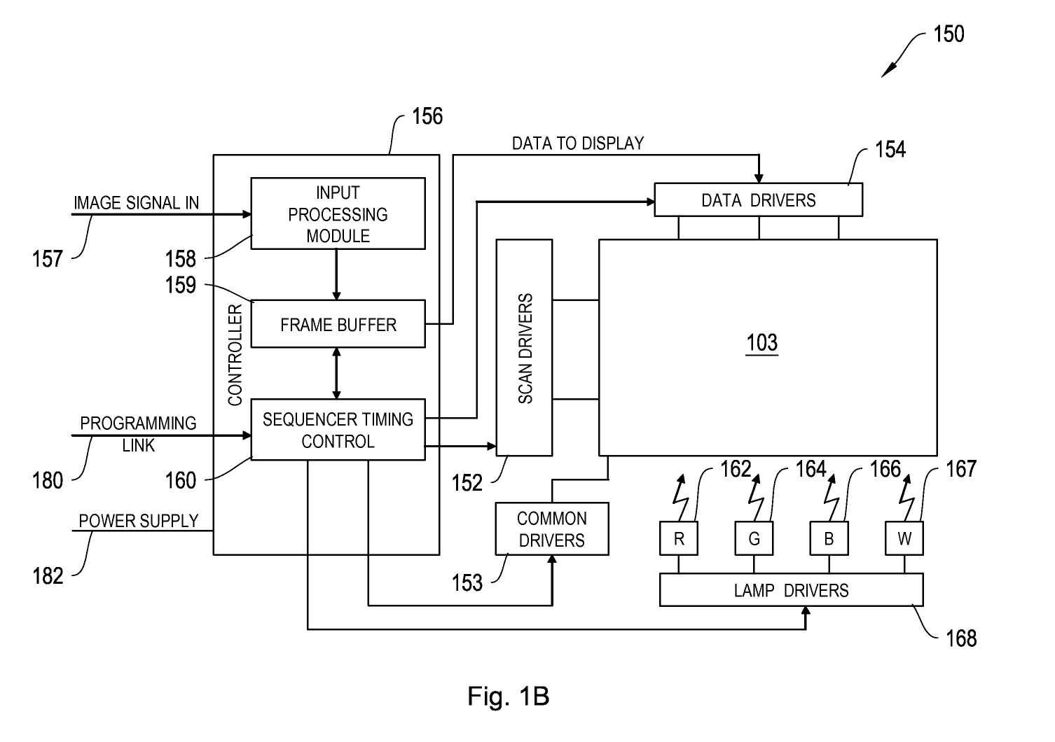

Particular implementations of the subject matter described in this disclosure can be implemented to realize one or more of the following potential advantages. The systems and methods described herein may reduce the deleterious effects of stiction in a MEMS device by providing a beam that can deflect as two MEMS surfaces are driven together and store energy that can be released as a spring force which will drive apart the MEMS surfaces when an electrical force driving the MEMS surfaces together is released. Certain implementations of the subject matter described in this disclosure can be implemented to realize one or more of the following other potential advantages, including providing a beam that can store energy for driving apart two MEMS surfaces and that may include an electrode for driving the two MEMS surfaces together. Additionally, in certain implementations the beam may be arranged to contact at least one of the MEMS surfaces and to oppose the movement of that MEMS surface with sufficient force to allow that MEMS surface to move proximate to, but not into contact with, another MEMS surface. The separation between the two MEMS surfaces may reduce the likelihood of dielectric charging occurring under the influence of an electric field. FIG. 1A is an example of a display apparatus 100, according to an illustrative implementation. The display apparatus 100 includes a plurality of MEMS light modulators 102a-102d (generally “light modulators 102”) arranged in rows and columns. In the display apparatus 100, light modulators 102a and 102d are in the open state, allowing light to pass. Light modulators 102b and 102c are in the closed state, obstructing the passage of light. By selectively setting the states of the light modulators 102a-102d, the display apparatus 100 can form an image 104 for a backlit display, if illuminated by a lamp or lamps 105. Setting the state of a MEMS modulation, such as MEMS modulator 102a, involves actuating the MEMS modulator 102a to move an element within the modulator 102a from a first position to a second position. In the process of moving from one position to another, the element may contact another element or a surface within the modulator 102a. Stiction arises when the element being moved binds to another element or surface within the modulator 102a. Image formation may degrade if stiction binds a moving element within the array of MEMS modulators 102a-102d.

In another implementation, the apparatus may form an image by reflection of ambient light originating from the front of the apparatus. In another implementation, the apparatus may form an image by reflection of light from a lamp or lamps positioned in the front of the display, i.e. by use of a front light. In still another implementation, the apparatus may work in a transflective mode, reflecting both ambient light originating from the front of the apparatus and light from a backlight. In general, in one of the closed or open states, the light modulators 102 interfere with light in an optical path by, for example, and without limitation, blocking, reflecting, absorbing, filtering, polarizing, diffracting, or otherwise altering a property or path of the light.

In the display apparatus 100, each light modulator 102 corresponds to a pixel 106 in the image 104. In certain implementations, the display apparatus 100 may utilize a plurality of light modulators to form a pixel 106 in the image 104. For example, the display apparatus 100 may include three color-specific light modulators 102. By selectively opening one or more of the color-specific light modulators 102 corresponding to a particular pixel 106, the display apparatus 100 can generate a color pixel 106 in the image 104. In another example, the display apparatus 100 includes two or more light modulators 102 per pixel 106 to provide grayscale in an image 104. With respect to an image, a “pixel” corresponds to the smallest picture element defined by the resolution of the image. With respect to structural components of the display apparatus 100, the term “pixel” refers to the combined mechanical and electrical components utilized to modulate the light that forms a single pixel of the image.

In the implementation depicted in FIG. 1A, each light modulator 102 includes a shutter 108 and an aperture 109. To illuminate a pixel 106 in the image 104, the shutter 108 is positioned such that it allows light to pass through the aperture 109 towards a viewer. To keep a pixel 106 unlit, the shutter 108 is positioned such that it obstructs the passage of light through the aperture 109. The aperture 109 is defined by an opening patterned through a reflective or light-absorbing material. In transflective implementations, each light modulator modulates both light from the backlight 105, as well as ambient light. In one implementation, the apertures are not completely cleared of the reflective material that would otherwise be etched away to form the aperture. The remaining reflective material reflects incident light back towards a viewer to form a part of the image 104. In another implementation, the apertures are fully cleared, and the ambient light is reflected by a front-facing reflective layer positioned behind the lamp 105.

The display apparatus 100 also includes a control matrix connected to the substrate and to the light modulators for controlling the movement of the shutters. The control matrix provides electrical interconnections that allow for voltages to be applied to different components of the light modulator 102. In certain implementations, the control matrix includes a series of electrical interconnects (e.g., interconnects 110, 112, and 114), including a write-enable interconnect 110 (also referred to as a “scan-line interconnect”) per row of pixels, one data interconnect 112 for each column of pixels, and one common interconnect 114 providing a common voltage to all pixels, or at least to pixels from both multiple columns and multiples rows in the display apparatus 100. In response to the application of an appropriate voltage (the “write-enabling voltage”), the write-enable interconnect 110 for a given row of pixels prepares the pixels in the row to accept new shutter movement instructions. The data interconnects 112 communicate the new movement instructions in the form of data voltage pulses. The data voltage pulses applied to the data interconnects 112, in some implementations, directly contribute to an electrostatic movement of the shutters. In other implementations, the data voltage pulses control switches, e.g., transistors or other non-linear circuit elements that control the application of separate actuation voltages, which are typically higher in magnitude than the data voltages, to the light modulators 102. The application of these actuation voltages then results in the electrostatic driven movement of the shutters 108.

FIG. 1B is a block diagram 150 of the display apparatus 100 of FIG. 1A, according to one illustrative implementation. Referring to FIGS. 1A and 1B, in addition to the elements of the display apparatus 100 described above, as depicted in the block diagram 150, the display apparatus 100 includes a plurality of scan drivers 152 (also referred to as “write enabling voltage sources”) and a plurality of data drivers 154 (also referred to as “data voltage sources”). The scan drivers 152 apply write enabling voltages to scan-line interconnects 110. The data drivers 154 apply data voltages to the data interconnects 112. In some implementations of the display apparatus, the data drivers 154 are configured to provide analog data voltages to the light modulators, especially where the gray scale of the image 104 is to be derived in analog fashion. In analog operation the light modulators 102 are designed such that when a range of intermediate voltages is applied through the data interconnects 112 there results a range of intermediate open states in the shutters 108 and therefore a range of intermediate illumination states or gray scales in the image 104.

In other cases the data drivers 154 are configured to apply only a reduced set of 2, 3, or 4 digital voltage levels to the control matrix. These voltage levels are designed to set, in digital fashion, either an open state or a closed state to each of the shutters 108.

The scan drivers 152 and the data drivers 154 are connected to digital controller circuit 156 (also referred to as the “controller 156”). The controller 156 controls how voltages are applied to different components of the light modulators to control how the shutter moves relative to the aperture. The controller 156 includes an input processing module 158, which processes an incoming image signal 157 into a digital image format appropriate to the spatial addressing and the gray scale capabilities of the display 100. The pixel location and gray scale data of each image is stored in a frame buffer 159 so that the data can be fed out as needed to the data drivers 154. The data is sent to the data drivers 154 in mostly serial fashion, organized in predetermined sequences grouped by rows and by image frames. The data drivers 154 can include series to parallel data converters, level shifting, and for some applications digital to analog voltage converters.

The display 100 apparatus optionally includes a set of common drivers 153, also referred to as common voltage sources. In some implementations the common drivers 153 provide a DC common potential to all light modulators within the array of light modulators 103, for instance by supplying voltage to a series of common interconnects 114. In other implementations the common drivers 153, following commands from the controller 156, issue voltage pulses or signals to the array of light modulators 103, for instance global actuation pulses which are capable of driving and/or initiating simultaneous actuation of all light modulators in multiple rows and columns of the array 103.

The drivers (e.g., scan drivers 152, data drivers 154, and common drivers 153) for different display functions are time-synchronized by a timing-control module 160 in the controller 156. Timing commands from the module 160 coordinate the illumination of red, green and blue and white lamps (162, 164, 166, and 167 respectively) via lamp drivers 168, the write-enabling and sequencing of specific rows within the array of pixels 103, the output of voltages from the data drivers 154, and the output of voltages that provide for light modulator actuation.

The controller 156 determines the sequencing or addressing scheme by which each of the shutters 108 in the array 103 can be re-set to the illumination levels appropriate to a new image 104. New images 104 can be set at periodic intervals. For instance, for video displays, the color images 104 or frames of video are refreshed at frequencies ranging from 10 to 300 Hertz. In some implementations the setting of an image frame to the array 103 is synchronized with the illumination of the lamps 162, 164, and 166 such that alternate image frames are illuminated with an alternating series of colors, such as red, green, and blue, to provide field sequential color.

In alternative implementations, the array of pixels 103 and the control matrix that controls the pixels may be arranged in configurations other than rectangular rows and columns. For example, the pixels can be arranged in hexagonal arrays or curvilinear rows and columns. In general, as used herein, the term scan-line shall refer to any plurality of pixels that share a write-enabling interconnect.

In some implementations, the array of modulators may be divided into two or more groups with different spatial orientations with respect to their respective apertures. The input processing module 158 may additionally store a map of the spatial orientation of each pixel and process control signals prior to sending them on to the control matrix to determine the direction of motion to actuate each modulator from a light-blocking state to a light-transmissive state.

The display 100 includes a plurality of functional blocks including the timing control module 160, the frame buffer 159, scan drivers 152, data drivers 154, and drivers 153 and 168. Each block can be understood to represent either a distinguishable hardware circuit and/or a module of executable code. In some implementations the functional blocks are provided as distinct chips or circuits connected together by means of circuit boards and/or cables. Alternately, many of these circuits can be fabricated along with the pixel array 103 on the same substrate of glass or plastic. In other implementations, multiple circuits, drivers, processors, and/or control functions from block diagram 150 may be integrated together within a single silicon chip, which is then bonded directly to the transparent substrate holding pixel array 103.

The controller 156 includes a programming link 180 by which the addressing, color, and/or gray scale algorithms, which are implemented within controller 156, can be altered according to the needs of particular applications. Additionally, the programming link 180 may allow for different light modulator actuation techniques to be implemented, for example, to control the manner in which elements are moved within the light modulator. Thus, modulators that can move elements at different speeds may store and apply various algorithms to control the speed of modulation. In some implementations, the programming link 180 conveys information from environmental sensors, such as ambient light or temperature sensors, so that the controller 156 can adjust imaging modes or backlight power in correspondence with environmental conditions. The controller 156 also includes a power supply input 182 which provides the power needed for lamps as well as light modulator actuation. The drivers 152 153, 154, and/or 168 may also include or be associated with DC-DC converters for transforming an input voltage at 182 into various voltages sufficient for the actuation of shutters 108 or illumination of the lamps, such as lamps 162, 164, 166, and 167.

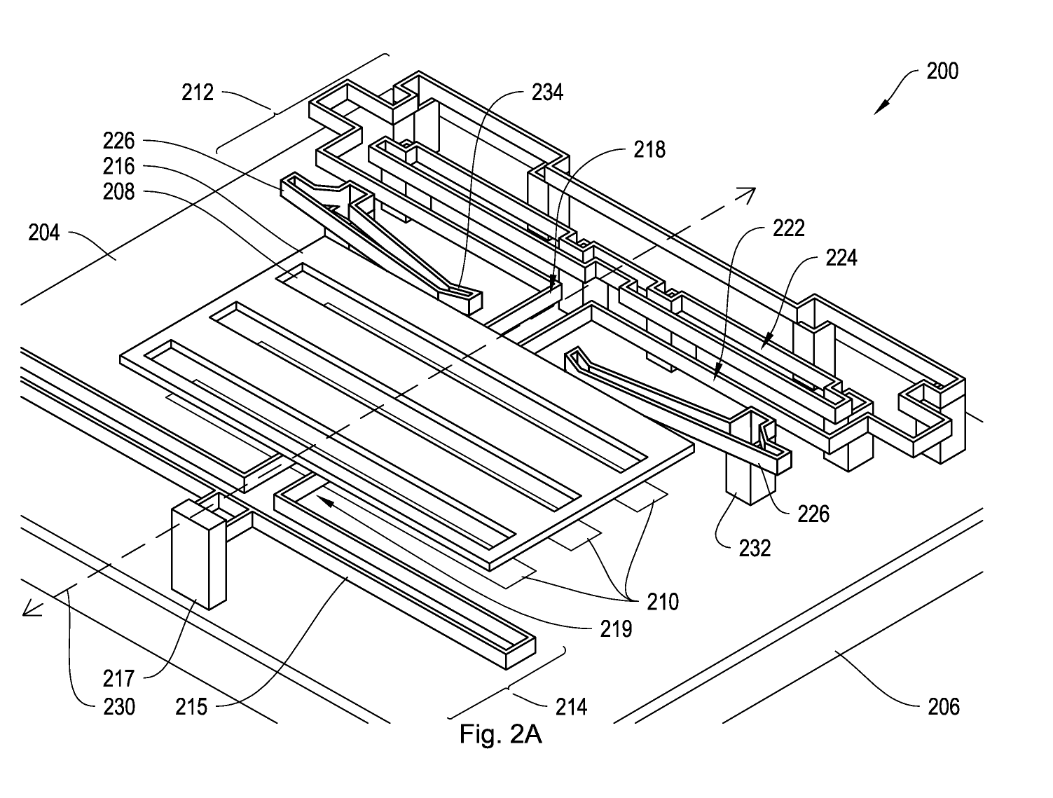

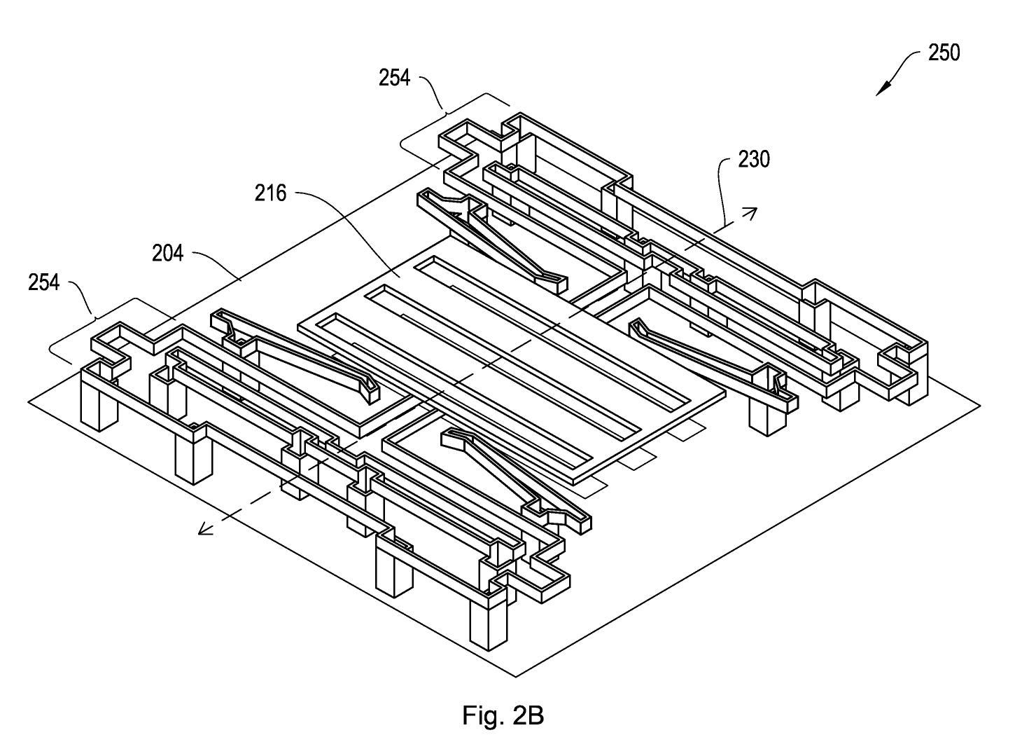

FIG. 2A depicts in more detail a light modulator of the type depicted in FIG. 1A. In particular, FIG. 2A depicts a light modulator 200 similar to the light modulators 102a-102d depicted in FIG. 1A. The light modulator 200 includes a shutter 216, and an actuator 212 disposed on a substrate 204 that is positioned on a light guide 206. The light modulator 200 is backlit and lamps, such as the lamps 162-167 of FIG. 1B, can illuminate the light guide 206. The light guide 206 distributes the lamp light beneath the substrate 204 to allow light to pass through the apertures 210 that are formed within the substrate 204. The apertures 210 may be openings, such as holes, formed in the substrate 204 to provide a path for light within the light guide 206 to pass toward the shutter 216. Alternatively, the apertures 210 may be transparent regions formed in the surface of the substrate 204 to allow light to pass from the light guide 206 to the shutter 216. In either case, the apertures 210 allow light to pass from the light guide 206 toward the shutter 216. The shutter 216 includes three apertures 208 that can be aligned with the apertures 210 by action of the actuator 212. The apertures 208 in shutter 216 may be through holes formed within the shutter 216 to allow light to pass through the shutter 216. In certain other implementations, the apertures 208 are formed by providing an optically transparent material that allows light passing through substrate apertures 210 to pass through the shutter apertures 208. In the implementation depicted in FIG. 2A, the shutter 216 has three apertures 208, each of which is a rectangle and each of which can be aligned with a respective rectangular substrate aperture 210. In other implementations, the shutter 216 and the substrate 204 may have more or fewer apertures and the apertures may be of different geometries. The number of apertures and their geometries will vary according to the specifications provided for the display.

A spring 214 attaches to the shutter 216 on a side of the shutter 216 opposite the actuator 212. The spring 214 includes a compliant beam 215. The compliant beam 215 may be a pliant wall of elastic semiconductor material, such as a pliant wall of amorphous silicon. In the depicted implementation, the compliant beam 215 is formed as a rectangular wall of elastic semiconductor material. On one side, the compliant beam 215 couples to a standoff anchor 217 that fixes one side of the rectangular compliant beam 215 to the substrate 204. The standoff anchor 217 also holds the compliant beam 215 away from the surface of the substrate 204, so that there is a separation between the compliant beam 215 and the surface of the substrate 204. The opposite side of the rectangular compliant beam 215 couples to a pair of connecting arms 219 that couple the compliant beam 215 to the shutter 216. The spring 214 provides a restorative force to the shutter 216. For example, when the shutter 216 is moved toward the actuator 212 in response to the actuator 212 being activated by a controller, such as the controller 156, the compliant beam 215 deforms by extending in the direction that the shutter 216 has moved. The deformed compliant beam 215 generates a spring force that opposes the motion of the shutter 216 toward the actuator 212. When the controller 156 deactivates the actuator 212, the spring force of the compliant beam 215 pulls the shutter 216 away from the actuator 212 into the position the shutter 216 was in before the actuator 212 drove the shutter 216 away from the spring 214.

The shutter 216 connects to a connecting rod 218 that connects to the actuator 212. The actuator 212 drives the shutter 216 in a path along the direction of the axis 230. The actuator 212, in certain implementations, connects to an interconnect layer formed within the substrate 204. The interconnect layer provides a control matrix like the control matrix described with reference to FIG. 1A. The actuator 212 includes an electrode 222 and an electrode 224. The electrode 222 connects to the connecting rod 218 that also connects to the shutter 216. The electrodes 222 and 224 and the connecting rod 218 may be made from any suitable material, and for example may be made from a semiconductor material such as amorphous silicon, epitaxial silicon or any other suitable material. The electrode 222 faces the electrode 224. In the implementation depicted in FIG. 2A, the connecting rod 218 couples the shutter 216 to the center of the electrode 222. The pair of electrodes 222 and 224 are drive electrodes that will, when activated, drive the electrode 222 toward the electrode 224, which drives the shutter 216 along a path defined by the axis 230. The spring 214 attached to the shutter 216 provides a restoring force that pulls the shutter 216 back toward the spring 214 when the actuator 212 is no longer actuating the drive electrodes 222 and 224.

Also shown in FIG. 2A is a pair of beams 226. The beams 226 are formed from thin walls of material, typically silicon. Each beam 226 attaches to a standoff anchor 232 that holds the beam 226 above the surface of the substrate 204. The standoff anchor 232 connects to the substrate 204 and extends from the substrate 204 to form a post. One portion of that post forms part of the thin wall of material that makes up the beam 226. The standoff anchor 232 provides a fixed point of attachment that connects the beam 226 to the surface of the substrate 204. The opposite end 234 of the beam 226 is suspended over the substrate 204 and is separated from the substrate 204 at that end 234.

The free end 234 of the beam 226 is placed close to, but not in contact with the shutter 216. When a controller activates the actuator 212, the electrode 222 moves toward the electrode 224 and pulls the shutter 216 toward the free ends 234 of the beams 226. As the actuator 212 drives the shutter 216 toward the electrode 224, the shutter 216 moves toward and into contact with the free ends 234 of the beams 226. The beams 226 deflect as the shutter 216 pushes on the free ends 234 and the deformed beams 226 generate a spring force that opposes the motion of the shutter 216 toward the electrode 224.

FIG. 2B depicts an alternate implementation of a light modulator of the type depicted in FIG. 1A. Specifically, FIG. 2B depicts a light modulator 250 having actuators 252 and 254. Each actuator 252 and 254 is similar in structure and operation to the actuator 212 of FIG. 2A. In the implementation of FIG. 2B the shutter 216 connects on opposite sides to respective ones of the actuators 252 and 254. The actuators 252 and 254 and suspend the shutter 216 a distance away from the substrate 204. In this implementation, a controller, such as controller 156, may control the operation of each actuator 252 and 254 to move the shutter 216 in a direction along the axis 230 to modulate light.

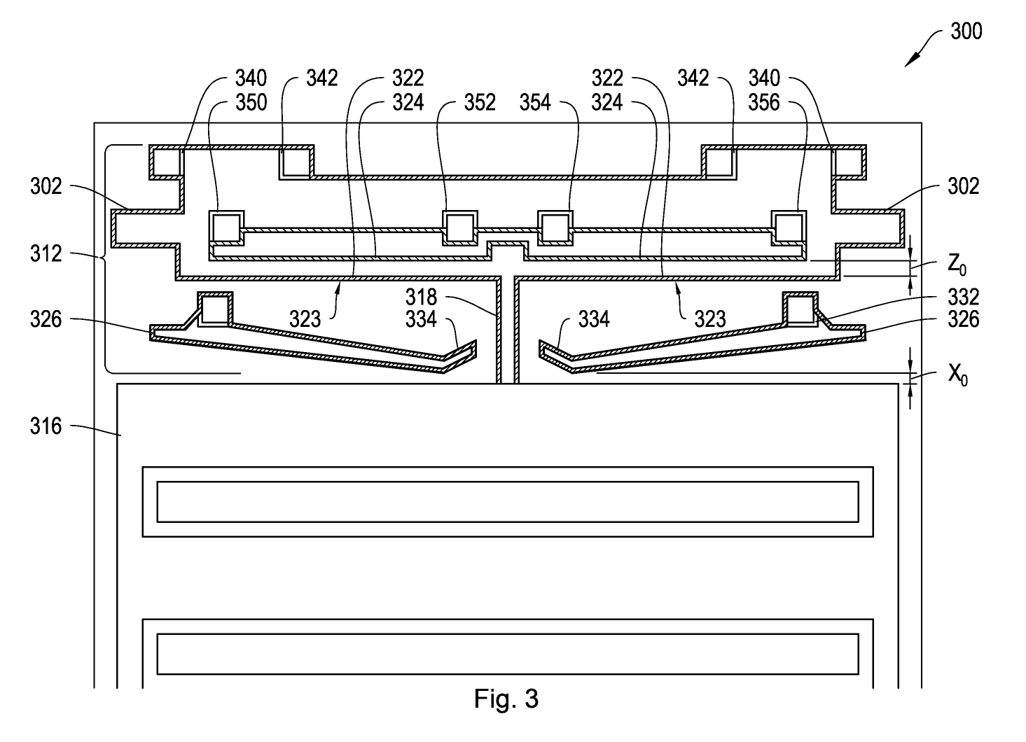

FIG. 3 is an actuator having deformable beams. In particular, FIG. 3 depicts a partial MEMS modulator shutter 300 of the type depicted in FIG. 2A. The modulator shutter 300 includes an actuator 312 having a pair of drive electrodes 322 and 324. The modulator shutter 300 also includes a shutter 316 that connects through a connecting rod 318 to the center of the actuator 312. The connecting rod 318 connects to the middle of the electrode 322. The electrode 322 has two end springs 302. The springs 302 are deformable walls of material, typically a semi-conductor silicon material such as amorphous silicon with a dielectric passivation. Optionally, the springs 302 may be metallic, such as Titanium (T) or Aluminum (Al). Any other suitable material providing sufficient elasticity and strength may be employed. The electrode 322 also couples to a pair of anchor points 340 and 342 that may be similar to the anchor posts 232 described with reference to FIG. 2A, that secure the electrode 322 to the surface of the substrate (not shown).

The electrode 322 is a wall of semiconductor material, such as amorphous silicon, that surrounds the electrode 324. Additionally, the electrode 322 is connected to the connecting rod 318 and the shutter 316, and the shutter 316 and connecting rod 318 are both electrically connected and part of the electrode 322. In one implementation, the shutter 316 and the connecting rod 318 are electrically connected and the shutter 316 and connecting rod 318 are at the same potential.

The electrode 322 includes a sidewall portion 323 that connects to springs 302 and the connecting rod 318. This sidewall portion 323 faces the electrode 324 and is separated from the electrode 324 by a distance Z_{O}. The optional springs 302 allow the sidewall portion 323 to move toward the electrode 324 when a voltage difference is applied across the electrode 322 and the electrode 324. The springs 302 are optional and in other implementations the electrode 322 is sufficiently compliant to allow for movement of the sidewall portion 323 toward the electrode 324 without need for these springs 302. The sidewall portion 323 allows the electrode 322 to be a movable electrode that is capable of traveling across the gap Z₀ that separates electrode 322 from electrode 324. The electrode 322 attaches to the standoff anchors 340 and 342, which may be posts of semiconductor material, such as amorphous silicon or any other suitable material. The standoff anchors 340 and 342 fix the wall of material that forms the electrode 322 to the surface of the substrate. Optionally, the standoff anchors 340 and 342 may connect to an electrical interconnect within the substrate. A controller, such as the controller 156, can apply a voltage to this interconnect to place a voltage on the electrode 322.

FIG. 3 further depicts that the electrode 324 is formed from a wall of material, typically some silicon based semi-conductor material such as amorphous silicon, that forms an electrode within the interior of the electrode 322. The electrode 324 is coupled to a series of standoff anchors 350, 352, 354, and 356 that secure the electrode 324 to the substrate supporting the actuator 312. The standoff anchors 350, 352, 354 and 356 may each have similar structure as the anchor post 232 shown in FIG. 2A. The electrode 324 may be a wall of material that is optionally sufficiently rigid to remain immobile when a voltage difference is placed across electrodes 322 and 324 and an electromotive force acts on the electrode 324. In other implementations, the electrode 324 may be compliant and capable of moving or bending as the voltage difference draws the electrodes 322 and 324 together. The standoff anchors 350, 352, 354 and 356 may connect to an electrical interconnect within the substrate to provide an electrical connection for applying a voltage to the electrode 324.

Beams 326 are disposed between the actuator 312 and the shutter 316. In certain implementations, there are a pair of beams 326, one on either side of the connecting rod 318. Each beam 326 may be a wall of semiconductor material, such as amorphous silicon, with a sidewall facing the shutter 316. The wall forming the beam 326 may be sufficiently thin to allow the beam 326 to elastically deform when the shutter 316 pushes on the beam 326. Each beam 326 has a free end 334 that is suspended over the substrate and which is free to move relative to the substrate. The opposite end of each beam 326 includes a standoff anchor 332 that secures the beam 326 to the substrate.

The standoff anchors 332 may connect to an electrical interconnect within the substrate to allow a voltage to be applied to the deformable beams 326. In certain implementations, the standoff anchors 332 couple to an interconnect that is electrically connected to the electrode 322. For example, the standoff anchor 332 may couple to an interconnect that also couples to the standoff anchor 340 and 342. A voltage applied to the standoff anchor 332 would establish substantially the same voltage on anchors 340 and 342. A standoff anchor 332 connects to a respective beam 326, which may be made of a semiconductor material, such as amorphous silicon. This will place the beam 326 at substantially the same voltage as the standoff anchor 332. Similarly, the electrode 322 couples to the standoff anchors 340 and 342 and will be placed at substantially the same voltage as the standoff anchors 340 and 342. The substantially similar voltages on the beams 326 and the electrode 322, which includes the connecting rod 318 and the shutter 316, prevents or limits a voltage difference from occurring between the electrode 322 and the beam 326.

As further depicted, the beam 326 is spaced away a distance X₀ from the shutter 316. This distance X₀ in this example is smaller than the distance Z₀ which represents the spacing between the electrodes 322 and 324. As the shutter 316 moves toward the electrode 324, the shutter 316 will contact the beams 326 before the electrode 322 contacts the electrode 324. This allows the beams 326 to compress as the shutter moves, and to generate a spring force that opposes the motion of the shutter 316. The relative size of the distances X₀ and Z₀ may be selected to achieve a spring force that will resist movement of the shutter 316 with a selected force. Optionally, the distances X₀ and Z₀ may be the same to provide an opposing spring force only upon contact of electrode 322 with electrode 324.

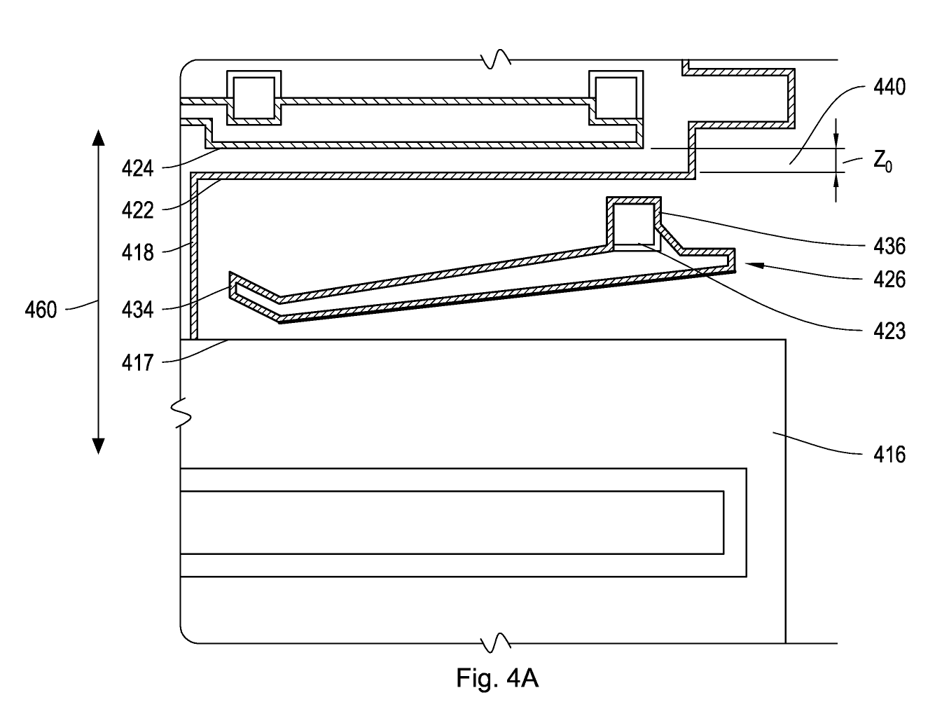

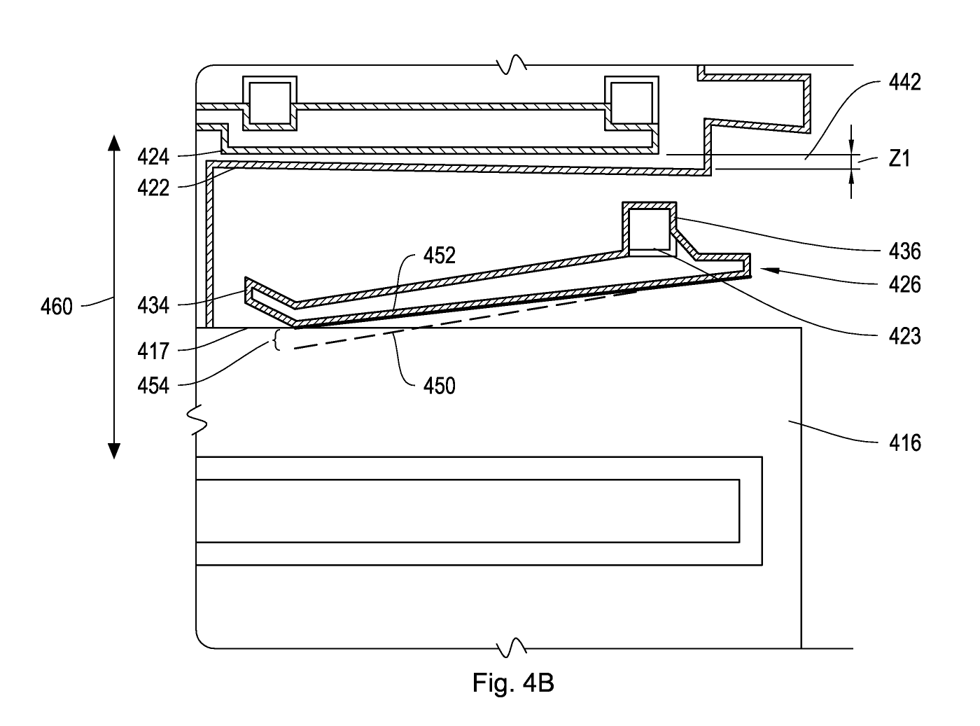

FIGS. 4A and 4B depict in more detail the action of the beam in opposing movement caused by the electrode pair depicted in FIG. 3. In particular, FIG. 4A depicts a portion of pair of the electrodes 422 and 424 that are spaced apart a distance Z₀ 440. The electrode 422, may move across gap 440 towards the electrode 424. As further shown in FIG. 4A, the electrode 422 couples via a connecting arm 418 to a shutter 416, which is illustrated only in part in FIG. 4A for the purpose of clarity. In particular, FIG. 4A illustrates the upper edge 417 of the shutter 416 and the portion of the shutter 416 that is proximate that edge 417 and adjacent the beam 426. Between the electrode 422 and the edge 417 of the shutter 416, is disposed the beam 426. The beam 426 has a free end 434 that is capable of moving in a direction along the axis 460. The beam 426 has a secured end 436 that couples to an anchor 423 that secures the beam 426 to a substrate (not shown). The beam 426 extends from the anchor 423 so that the free end 434 of the beam 426 is suspended above the substrate and the beam 426 forms a cantilever beam above the substrate.

FIG. 4A depicts the electrode pair 422 and 424 in a neutral state. Typically, a neutral state occurs when the voltage applied to the electrode 422 is substantially the same as the voltage applied to the electrode 424, that is the voltage difference between the electrodes 422 and 424 is less than a certain threshold. In the neutral state, the drive electrodes 422 and 424 are separated by the gap 440 shown as Z₀ in FIG. 4A. In one implementation, the gap Z₀ is maintained by a spring, such as the spring 302 depicted in FIG. 3 and/or spring 214 depicted in FIG. 2A, or some other coupling capable of securing the electrode 422 in a manner that holds electrode 422 away from the electrode 424 but allows the electrode 422 to move in a direction along the axis 460.

FIG. 4B depicts the electrodes 422 and 424 in the actuated state. As illustrated in FIG. 4B in the actuated state, the electrode 422 is driven across the gap Zₒ toward electrode 424. In the illustrated implementation, the electrode 422 is separated from electrode 424 by a gap Z₁ indicated by the lines 442. The gap Z₁ is substantially smaller than the gap Z₀ of the neutral state. The movement of electrode 422 drives the edge 417 of the shutter 416 toward the electrode 424, and against the free-end 434 of the beam 426. The electrode 422 may be driven toward electrode 424 by the application of a voltage difference applied across the electrodes 422 and 424. The voltage difference creates an electromotive force that drives the movable electrode 422 toward the electrode 424, which is typically fixed to the substrate and relatively immovable compared to movable electrode 422. The electromotive force driving the electrode 422, also drives shutter 416 against the free end 434 of the beam 426. As illustrated in FIG. 4B, the beam 426 will deflect and free-end 434 of the beam 426 toward the electrode 422. In the illustrated implementation, the beam 426 is displaced from its initial position as illustrated by the dash line 450 to the new position, 452. The distance between the original position 450 and the new position 452 is the distance 454 indicated by the dashed lines between the original position 450 and the new position 452. The distance 454 is typically close to or equal to the distance Z₀ 440.

In one implementation, the beam 426 is formed of an elastic material or a least a material that acts elastically for the range of deflection expected for this application. In one implementation, the beam 426 is formed of an amorphous silicon material of the type commonly used in semiconductor manufacturing. This amorphous silicon material is sufficiently elastic over a limited range of deformation to provide the beam 426 with a spring like action that will generate a spring force proportional to the displacement of the spring 426 from its initial position.

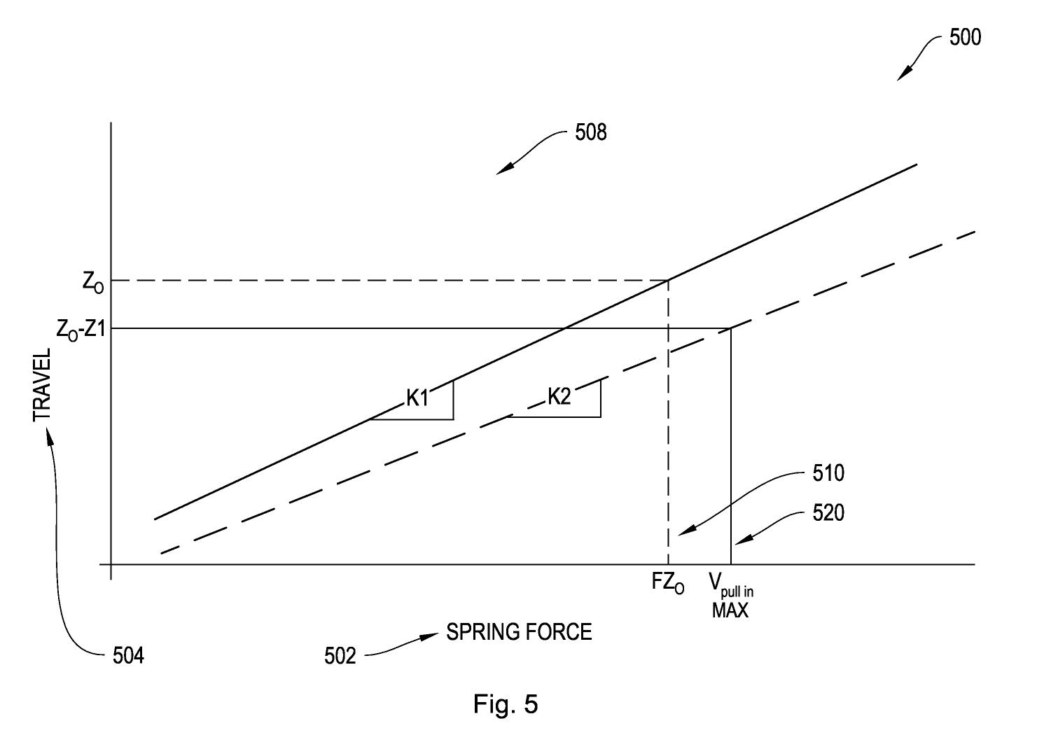

FIG. 5 is a graph illustrating the spring force of one implementation of a beam. In particular, FIG. 5 depicts a graph 500 that shows spring force on the X-axis 502 and travel distance of the spring along Y-axis 504. For this graph, travel distance represents the distance of displacement of the free-end 434 of the spring 436 from its neutral position and along the axis of motion 460. FIG. 5 shows that over a limited range of travel, the compliant beam 426 has a relatively constant spring force, K1. Additionally, FIG. 5 depicts that for a displacement Z₀, the spring force generated is approximately the spring-force F_{Z0} 510.

The spring force 510 represents the force of the beam 426 acting on the edge 417 of the shutter 416 and having a direction for driving the shutter 416 away from the electrode 424 and along the path indicated by the axis 460. The force F_{Z0} 510 drives the electrodes 422 and 424 apart. This opposing spring force can overcome, at least in part, stiction binding the electrodes 422 and 424 together.

In certain implementations, the spring force of the beam 426 is selected to limit the movement of the electrode 422 to, for example, prevent electrode 422 from contacting electrode 424. In certain implementations, spring force is selected by selecting the width of the beam 422. FIG. 5 shows a dashed line representing a second different spring force K2. As shown in FIG. 5, the beam 426 can have a spring force K2 calibrated to generate a force equal to the maximum pull in electromotive force generated by the expected voltage differential applied between electrodes 422 and 424. This spring force K2 is generated when the free end 434 of the beam 426 has traveled less than the distance Z₀ 440. In particular, as shown in FIG. 5, the spring force 520 representing the maximum pull in force for the applied voltage differential, can occur at a travel of Z₀-Z₁. In this implementation, the opposing force of the beam 426 is sufficiently large to prevent the electrode 422 from traveling the full distance Z₀ toward the electrode 424. In this implementation, in the actuated state depicted in FIG. 4B, the electrode 422 is spaced a distance Z₁ away from the electrode 424. In this way, the beam 426 can prevent the electrode 422 from contacting the electrode 424 and thereby reduce the likelihood or prevent the occurrence of stiction between the two electrodes 422 and 424.

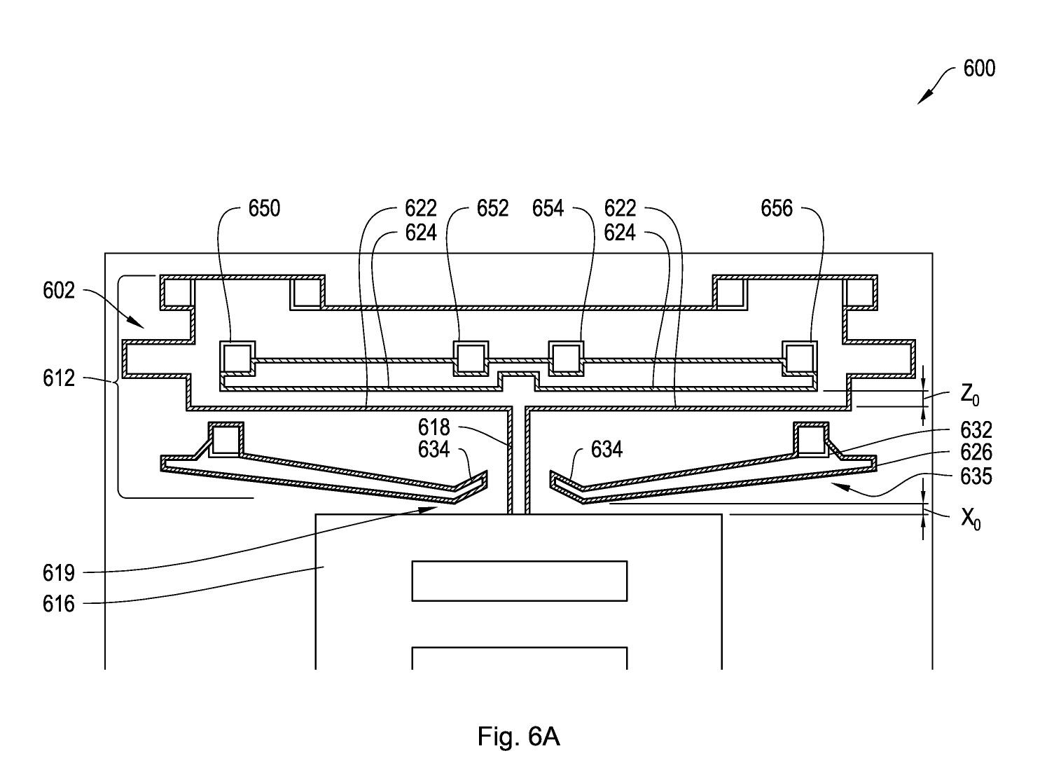

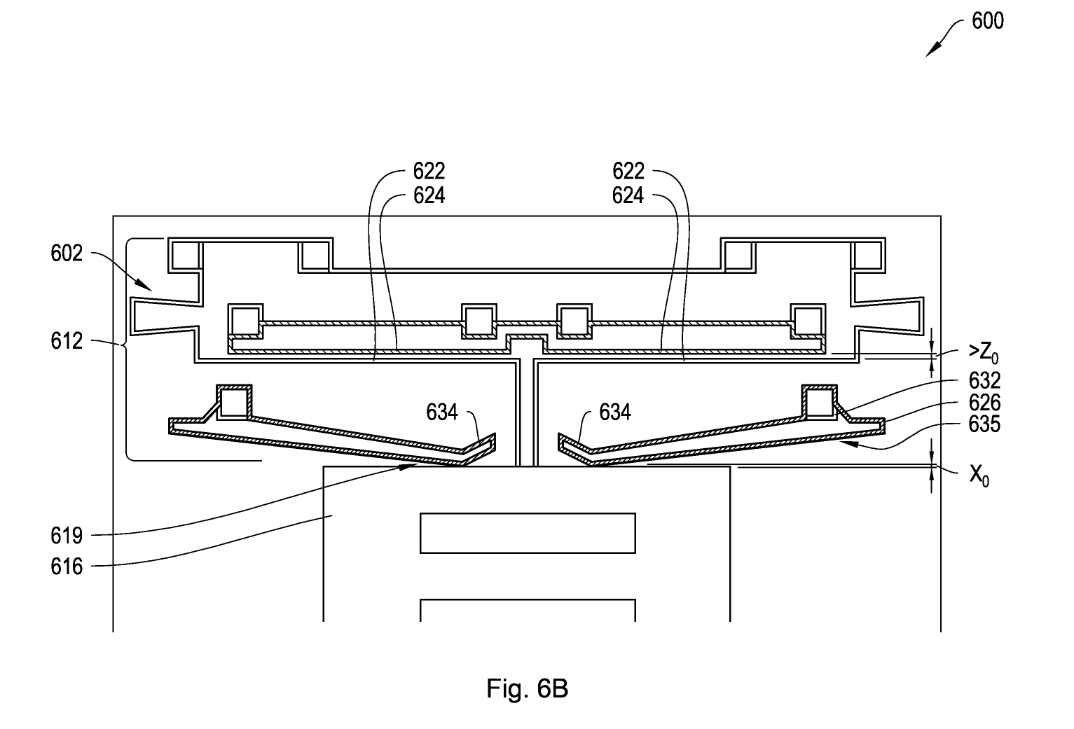

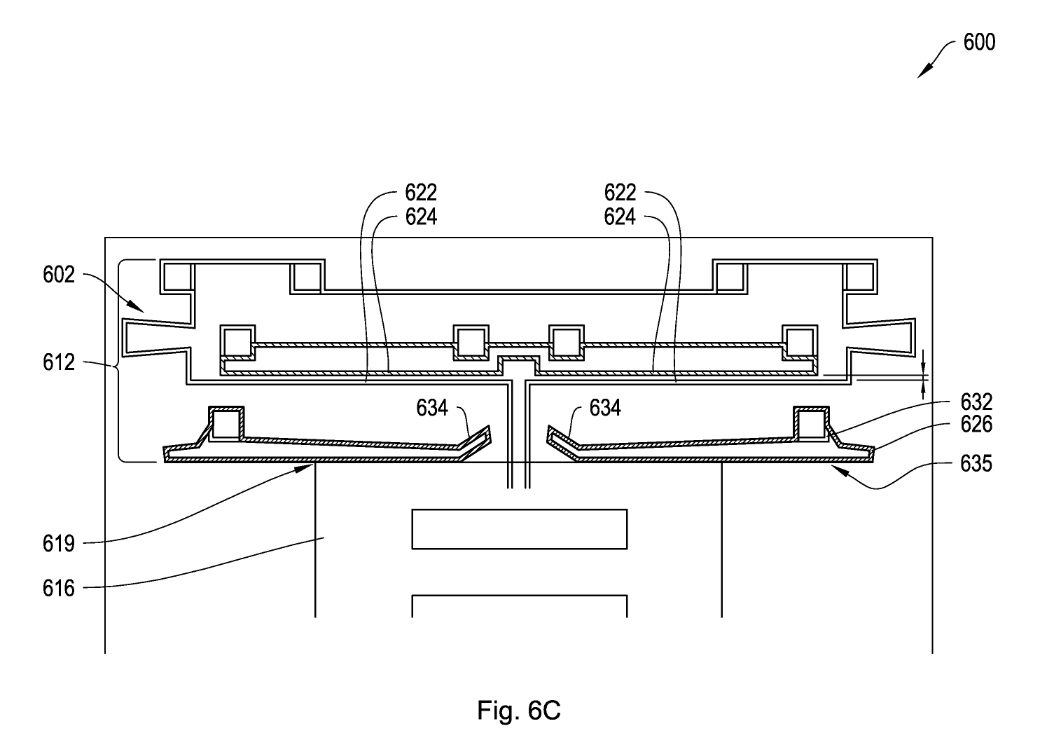

FIGS. 6A, 6B and 6C are a MEMS device having a deflecting beam with an electrode.

In particular, FIG. 6A illustrates an actuator 612 that connects by a connecting arm 618 to a shutter 616. The actuator 612 includes a pair of electrodes 622 and 624 that are separated by a gap Z₀. The electrode 622 is capable of moving across the gap Z₀ toward the electrode 624. As illustrated in FIG. 6A, the electrode 622 connects to the connecting arm 618. In this implementation, the electrode 622 includes the connecting arm 618 and at least the portion of the shutter 616 that includes the side wall portion 619 of the shutter 616. For purposes of clarity, the electrode 622 in FIG. 6A is presented in a dashed line. The dashed line of electrode 622 shows that the electrode 622 includes the connecting arm 618 and the side wall 619 and the side wall portion 619 of the shutter 616 that faces the beam 626.

The beam 626 includes a side wall that faces the side wall portion 619 of the shutter 616. In this implementation, the side wall of the beam 626 may be an electrode that is electrically connected to the electrode 624 via an electrical interconnect (not shown). For purposes of illustration, the electrode 624 is depicted as a heavy black line, and similarly, the side wall of the beam 626 is also illustrated as a heavy black line to indicate that the side wall of the beam 626 is electrically connected to the electrode 624 via an electrical interconnect (not shown). The sidewall of the beam 626 is a linear wall, although in other implementations the shape may vary. For example the beam 626 may be curved or arcuate so that the sidewall of the beam 626 curves or arcs along its length from the anchor 632 to the end 634 of the beam. Other shapes may be used depending on the application. In one implementation, the electrical connection between the side wall of the beam 626 and the electrode 624 is through an interconnect layer formed within the substrate supporting the actuator 612 and the shutter 616. In this implementation, the stand off anchor 632 may couple to an interconnect in the substrate and that interconnect may connect to the anchor standoffs 650, 652, 654 and 656 that are coupled to electrode 624. A voltage applied to electrode 624 will also be applied, via the interconnect, to the beam 626. This electrical connection allows that beam 626 and the shutter 616 to act as an electrode pair.

FIG. 6A illustrates that the beam 626 is spaced a distance Xₒ from the shutter 616. FIG. 6A further depicts that the spacing X₀ is smaller than the spacing Z₀ between the electrodes 622 and 624. In operation, a voltage controller, such as controller 156, may apply a voltage difference between the electrode 624 and the electrode 622. The shutter 616 is electrically connected to, and part of, the electrode 622 and at the same voltage as the electrode 622. The beam 626 is electrically connected, through an interconnect layer (not shown) to the electrode 624. The voltage difference between the shutter 616 and the beam 626 creates an electromotive pull-in force that draws the shutter 616 toward the beam 626, and causes the springs 602 to compress. In this way the beam 626 acts as a beam electrode that can be paired with the shutter 616. Similarly, the voltage difference between the electrode 622 and the electrode 624 causes the electrode 622 to move toward the electrode 624, and further causes the springs 602 to compress. FIG. 6B illustrates a first stage of movement. The shutter 616 is drawn toward the beams 626, and travels the distance X₀ to make contact with the beams 626. Once contact is made, the interconnect coupling the beam 626 with the electrode 624 is deactivated so that the beam 626 and the electrode 624 are no longer electrically connected. In one implementation, a transistor switch can couple the interconnect to the beam 626. The transistor switch can be switched between an open and closed state to connect and disconnect the beam 626 to the interconnect, and to connect and disconnect the beam 626 to the electrode 622. By disconnecting the beam 626 from the interconnect coupled to electrode 624 and coupling the beam 626 to the electrode 622, the voltage difference between the beam 626 and the shutter 616 is removed. In an alternative implementation, the beam 626 and the shutter 616, or at least the sidewalls of these elements that will make contact, have a layer of passivation. The passivation layer may be thick enough to prevent a short circuit from occurring when the beam 626 and shutter 616 are drawn into contact. Any suitable passivating layer may be used that will adhere to the beam 626 and to the shutter 616 and provide a breakdown voltage characteristic that is higher than the expected voltage difference between the beam 626 and the shutter 616. FIG. 6C illustrates the second stage of the actuator wherein the electrode 622 has been moved a distance X₀ closer to the electrode 624. A voltage difference between the electrodes 622 and 624 will drive the electrode 622 the remaining distance across the gap Z₀. In certain other implementations, the beam 626 connects to an interconnect that may be separately driven by a controller, such as the controller 156. In this implementation, the beam 626 may have a different voltage applied to it by the controller than the voltage applied to electrode 624. The ability to set one voltage difference between the sidewall of the beam 626 and the sidewall portion of the shutter 616, and to set another, different voltage difference between the electrodes 622 and 624, allows the actuator 612 to set up a voltage gradient for driving the shutter.

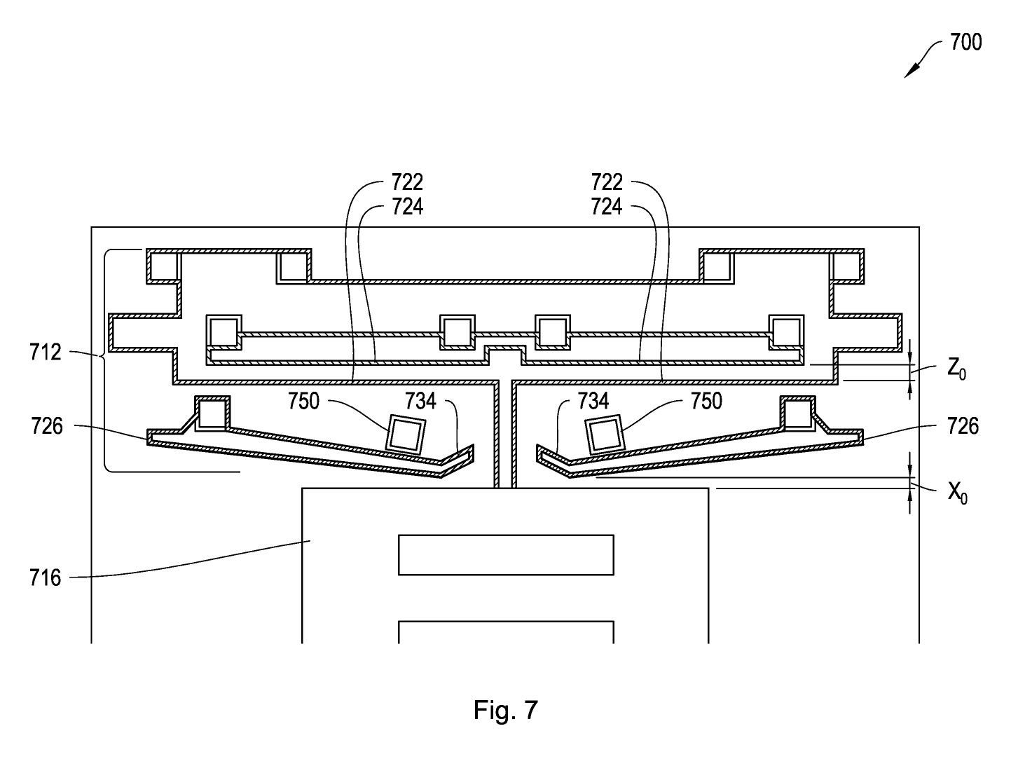

FIG. 7 is an alternate implementation having a mechanical stop. In particular, FIG. 7 depicts a partial view of a shutter 700 that includes an actuator 712 that has two compliant beams 726 disposed between a pair of driving electrodes 724 and 722 and a shutter 716.

A mechanical stop 750 is disposed between the electrode 722 and the beam 726. The mechanical stop 750 is spaced away from the beam 726 and is arranged on the surface of the substrate to stop the beam 726 from traveling toward the actuator 712 further than the location of the mechanical stop 750. The mechanical stop 750 blocks the free end 734 of the beam 726 from traveling as far as the beam 726 is capable of deforming. In certain implementations, the mechanical stop 750 is spaced sufficiently close to the beam 726 to establish a point at which the beam 726 and therefore the shutter 716 can not deflect or move beyond, thereby preventing electrode 722 from coming into contact with the electrode 724. Thus, the mechanical stop 750 should prevent the shutter 716 from traveling a distance equal to or greater than the distance Z₀. In other implementations, the mechanical stop 750 can be placed at other distances from the beam 726 for other purposes, such as for preventing the beam 726 from deflecting to an extent that it may cause permanent damage to the material structure of the beam 726. In still other applications, the mechanical stop 750 can be placed in other locations that achieve other results beneficial to the system.

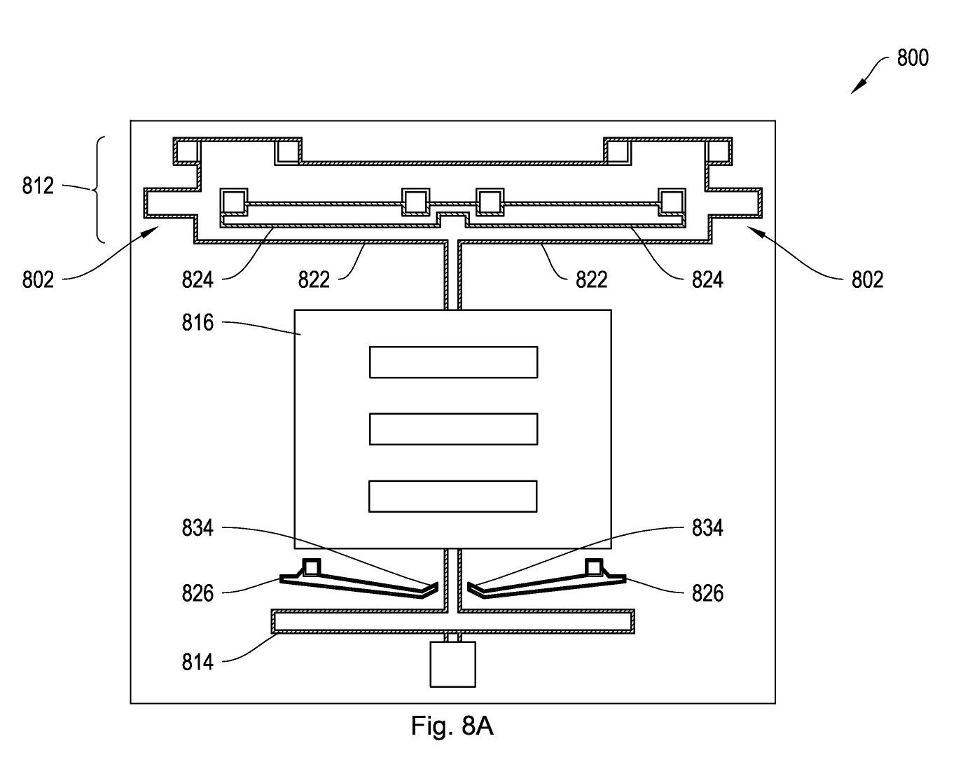

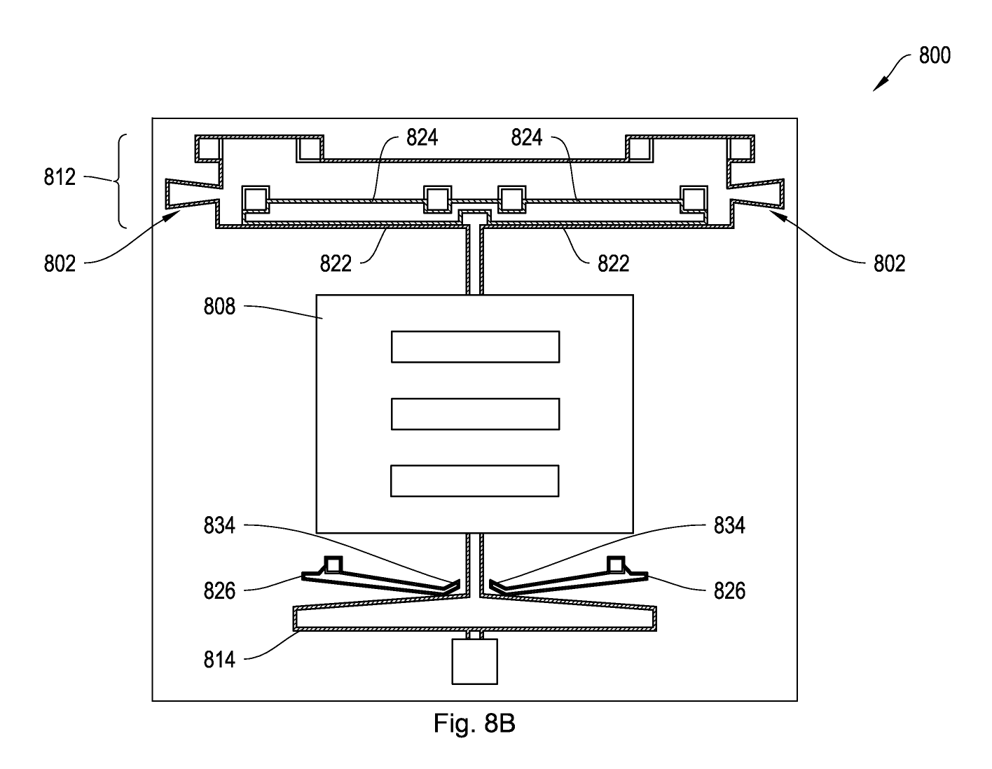

FIGS. 8A and 8B illustrate certain implementations having deformable beams acting on a spring. In particular, FIG. 8A depicts a light modulator 800 that has a shutter 816 that connects between an actuator 812 and a spring 814. The spring 814 can provide a restoring force that will move the shutter 816 away from the actuator 812 when the actuator 812 is deactivated. As is further depicted in FIG. 8A, a pair of deformable beams 826 are arranged between the spring 814 and the shutter 816. The deformable beams 826 are similar to the deformable beams 326 described with reference to FIG. 3. FIG. 8A shows the light modulator 800 in the neutral position. FIG. 8B depicts the light modulator 800 in the actuated position. In FIG. 8B the electrode 822 is moved against and substantially into contact with the electrode 824. The spring 814 is extended in the direction of the actuator 812 and has been brought into contact with the free ends 834 of the deformable beams 826. The deformable beams 826 provide an opposing spring force that tends to drive the spring 814 away from the actuator 812. As the spring 814 is connected to the shutter 816 and the shutter 816 is connected to the electrode 822, the action of the deformable beams 826 in driving the spring 814 away from the actuator 812, tends to overcome stiction forces that may be binding the electrode 822 to the electrode 824.

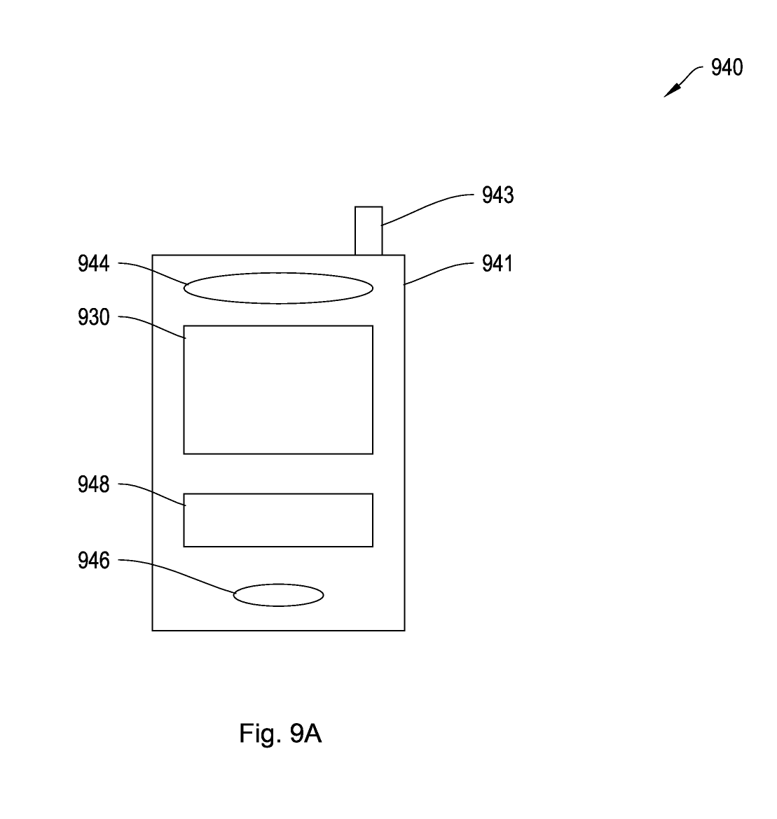

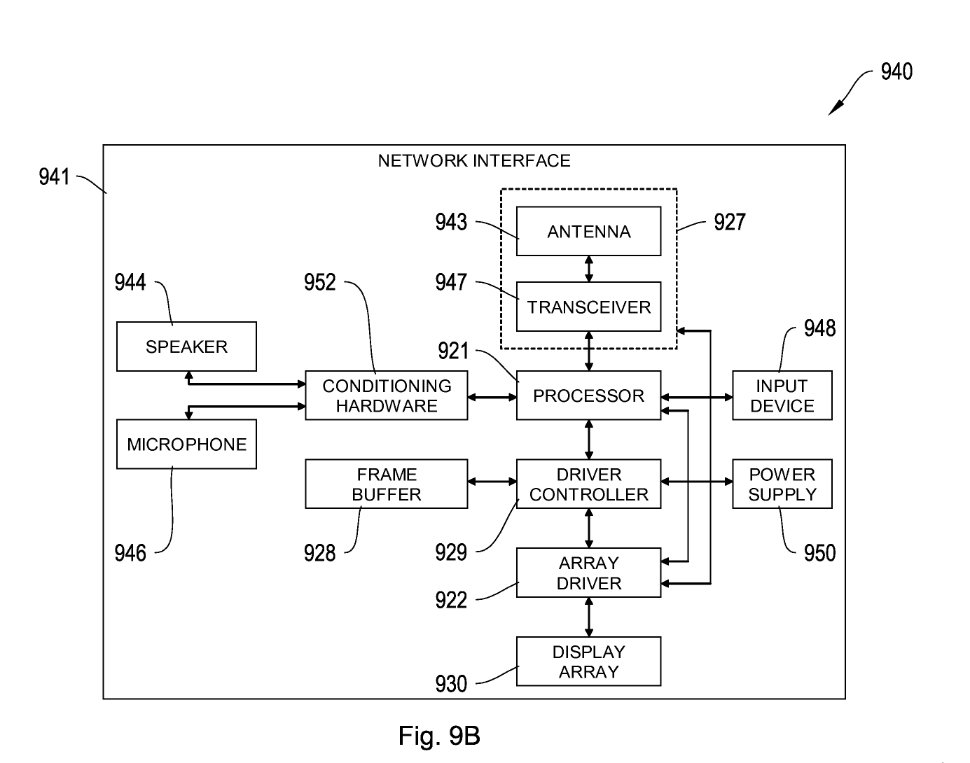

FIGS. 9A and 9B are system block diagrams illustrating a display device 940 that includes a plurality of MEMS displays elements, including for example, DMS display elements. The display device 940 can be, for example, a smart phone, a cellular or mobile telephone. However, the same components of the display device 940 or slight variations thereof are also illustrative of various types of display devices such as televisions, computers, tablets, e-readers, hand-held devices and portable media devices.

The display device 940 includes a housing 941, a display 930, an antenna 943, a speaker 945, an input device 948 and a microphone 946. The housing 941 can be formed from any of a variety of manufacturing processes, including injection shuttering, and vacuum forming. In addition, the housing 941 may be made from any of a variety of materials, including, but not limited to: plastic, metal, glass, rubber and ceramic, or a combination thereof. The housing 941 can include removable portions (not shown) that may be interchanged with other removable portions of different color, or containing different logos, pictures, or symbols.

The display 930 may be any of a variety of displays, including a bi-stable or analog display, as described herein. The display 930 also can be configured to include a flat-panel display, such as plasma, EL, OLED, STN LCD, or TFT LCD, or a non-flat-panel display, such as a CRT or other tube device. In addition, the display 930 can include, for example, a MEMS element based, as described herein.

The components of the display device 940 are schematically illustrated in FIG. [9B]. The display device 940 includes a housing 941 and can include additional components at least partially enclosed therein. For example, the display device 940 includes a network interface 927 that includes an antenna 943 which can be coupled to a transceiver 947. The network interface 927 may be a source for image data that could be displayed on the display device 940. Accordingly, the network interface 927 is one example of an image source module, but the processor 921 and the input device 948 also may serve as an image source module. The transceiver 947 is connected to a processor 921, which is connected to conditioning hardware 952. The conditioning hardware 952 may be configured to condition a signal (such as filter or otherwise manipulate a signal). The conditioning hardware 952 can be connected to a speaker 945 and a microphone 946. The processor 921 also can be connected to an input device 948 and a driver controller 929. The driver controller 929 can be coupled to a frame buffer 928, and to an array driver 922, which in turn can be coupled to a display array 930. One or more elements in the display device 940, including elements not specifically depicted in FIG. 9B, can be configured to function as a memory device and be configured to communicate with the processor 921. In some implementations, a power supply 950 can provide power to substantially all components in the particular display device 940 design.

The network interface 927 includes the antenna 943 and the transceiver 947 so that the display device 940 can communicate with one or more devices over a network. The network interface 927 also may have some processing capabilities to relieve, for example, data processing requirements of the processor 921. The antenna 943 can transmit and receive signals. In some implementations, the antenna 943 transmits and receives RF signals according to the IEEE 16.11 standard, including IEEE 16.11(a), (b), or (g), or the IEEE 802.11 standard, including IEEE 802.11a, b, g, n, and further implementations thereof. In some other implementations, the antenna 943 transmits and receives RF signals according to the Bluetooth® standard. In the case of a cellular telephone, the antenna 943 can be designed to receive code division multiple access (CDMA), frequency division multiple access (FDMA), time division multiple access (TDMA), Global System for Mobile communications (GSM), GSM/General Packet Radio Service (GPRS), Enhanced Data GSM Environment (EDGE), Terrestrial Trunked Radio (TETRA), Wideband-CDMA (W-CDMA), Evolution Data Optimized (EV-DO), 1xEV-DO, EV-DO Rev A, EV-DO Rev B, High Speed Packet Access (HSPA), High Speed Downlink Packet Access (HSDPA), High Speed Uplink Packet Access (HSUPA), Evolved High Speed Packet Access (HSPA+), Long Term Evolution (LTE), AMPS, or other known signals that are used to communicate within a wireless network, such as a system utilizing 3G, 4G or 5G technology. The transceiver 947 can pre-process the signals received from the antenna 943 so that they may be received by and further manipulated by the processor 921. The transceiver 947 also can process signals received from the processor 921 so that they may be transmitted from the display device 940 via the antenna 943.

In some implementations, the transceiver 947 can be replaced by a receiver. In addition, in some implementations, the network interface 927 can be replaced by an image source, which can store or generate image data to be sent to the processor 921. The processor 921 can control the overall operation of the display device 940. The processor 921 receives data, such as compressed image data from the network interface 927 or an image source, and processes the data into raw image data or into a format that can be readily processed into raw image data. The processor 921 can send the processed data to the driver controller 929 or to the frame buffer 928 for storage. Raw data typically refers to the information that identifies the image characteristics at each location within an image. For example, such image characteristics can include color, saturation and gray-scale level.

The processor 921 can include a microcontroller, CPU, or logic unit to control operation of the display device 940. The conditioning hardware 952 may include amplifiers and filters for transmitting signals to the speaker 945, and for receiving signals from the microphone 946. The conditioning hardware 952 may be discrete components within the display device 940, or may be incorporated within the processor 921 or other components.

The driver controller 929 can take the raw image data generated by the processor 921 either directly from the processor 921 or from the frame buffer 928 and can re-format the raw image data appropriately for high speed transmission to the array driver 922. In some implementations, the driver controller 929 can re-format the raw image data into a data flow having a raster-like format, such that it has a time order suitable for scanning across the display array 930. Then the driver controller 929 sends the formatted information to the array driver 922. Although a driver controller 929, such as an LCD controller, is often associated with the system processor 921 as a stand-alone Integrated Circuit (IC), such controllers may be implemented in many ways. For example, controllers may be embedded in the processor 921 as hardware, embedded in the processor 921 as software, or fully integrated in hardware with the array driver 922.

The array driver 922 can receive the formatted information from the driver controller 929 and can re-format the video data into a parallel set of waveforms that are applied many times per second to the hundreds, and sometimes thousands (or more), of leads coming from the display's x-y matrix of display elements.

In some implementations, the driver controller 929, the array driver 922, and the display array 930 are appropriate for any of the types of displays described herein. For example, the driver controller 929 can be a conventional display controller or a bi-stable display controller (such as a MEMS element display controller, including for example, a DMS display controller). Additionally, the array driver 922 can be a conventional driver or a bi-stable display driver (such as a MEMS element display driver, including for example, a DMS element display driver). Moreover, the display array 930 can be a conventional display array or a bi-stable display array (such as a display including an array of MEMS elements, including for example, DMS display elements). In some implementations, the driver controller 929 can be integrated with the array driver 922. Such an implementation can be useful in highly integrated systems, for example, mobile phones, portable-electronic devices, watches or small-area displays.

In some implementations, the input device 948 can be configured to allow, for example, a user to control the operation of the display device 940. The input device 948 can include a keypad, such as a QWERTY keyboard or a telephone keypad, a button, a switch, a rocker, a touch-sensitive screen, a touch-sensitive screen integrated with the display array 930, or a pressure- or heat-sensitive membrane. The microphone 946 can be configured as an input device for the display device 940. In some implementations, voice commands through the microphone 946 can be used for controlling operations of the display device 940.

The power supply 950 can include a variety of energy storage devices. For example, the power supply 950 can be a rechargeable battery, such as a nickel-cadmium battery or a lithium-ion battery. In implementations using a rechargeable battery, the rechargeable battery may be chargeable using power coming from, for example, a wall socket or a photovoltaic device or array. Alternatively, the rechargeable battery can be wirelessly chargeable. The power supply 950 also can be a renewable energy source, a capacitor, or a solar cell, including a plastic solar cell or solar-cell paint. The power supply 950 also can be configured to receive power from a wall outlet.

In some implementations, control programmability resides in the driver controller 929 which can be located in several places in the electronic display system. In some other implementations, control programmability resides in the array driver 922. The above-described optimization may be implemented in any number of hardware and/or software components and in various configurations.

As used herein, a phrase referring to “at least one of” a list of items refers to any combination of those items, including single members. As an example, “at least one of: a, b, or c” is intended to cover: a, b, c, a-b, a-c, b-c, and a-b-c.

The various illustrative logics, logical blocks, modules, circuits and algorithm steps described in connection with the implementations disclosed herein may be implemented as electronic hardware, computer software, or combinations of both. The interchangeability of hardware and software has been described generally, in terms of functionality, and illustrated in the various illustrative components, blocks, modules, circuits and steps described above. Whether such functionality is implemented in hardware or software depends upon the particular application and design constraints imposed on the overall system.

The hardware and data processing apparatus used to implement the various illustrative logics, logical blocks, modules and circuits described in connection with the aspects disclosed herein may be implemented or performed with a general purpose single- or multi-chip processor, a digital signal processor (DSP), an application specific integrated circuit (ASIC), a field programmable gate array (FPGA) or other programmable logic device, discrete gate or transistor logic, discrete hardware components, or any combination thereof designed to perform the functions described herein. A general purpose processor may be a microprocessor, or, any conventional processor, controller, microcontroller, or state machine. A processor also may be implemented as a combination of computing devices, such as a combination of a DSP and a microprocessor, a plurality of microprocessors, one or more microprocessors in conjunction with a DSP core, or any other such configuration. In some implementations, particular steps and methods may be performed by circuitry that is specific to a given function.

In one or more aspects, the functions described may be implemented in hardware, digital electronic circuitry, computer software, firmware, including the structures disclosed in this specification and their structural equivalents thereof, or in any combination thereof. Implementations of the subject matter described in this specification also can be implemented as one or more computer programs, i.e., one or more modules of computer program instructions, encoded on a computer storage media for execution by, or to control the operation of, data processing apparatus.

If implemented in software, the functions may be stored on or transmitted over as one or more instructions or code on a computer-readable medium. The steps of a method or algorithm disclosed herein may be implemented in a processor-executable software module which may reside on a computer-readable medium. Computer-readable media includes both computer storage media and communication media including any medium that can be enabled to transfer a computer program from one place to another. A storage media may be any available media that may be accessed by a computer. By way of example, and not limitation, such computer-readable media may include RAM, ROM, EEPROM, CD-ROM or other optical disk storage, magnetic disk storage or other magnetic storage devices, or any other medium that may be used to store desired program code in the form of instructions or data structures and that may be accessed by a computer. Also, any connection can be properly termed a computer-readable medium. Disk and disc, as used herein, includes compact disc (CD), laser disc, optical disc, digital versatile disc (DVD), floppy disk, and blu-ray disc where disks usually reproduce data magnetically, while discs reproduce data optically with lasers. Combinations of the above also may be included within the scope of computer-readable media. Additionally, the operations of a method or algorithm may reside as one or any combination or set of codes and instructions on a machine readable medium and computer-readable medium, which may be incorporated into a computer program product.

Various modifications to the implementations described in this disclosure may be readily apparent to those skilled in the art, and the generic principles defined herein may be applied to other implementations without departing from the spirit or scope of this disclosure. Thus, the claims are not intended to be limited to the implementations shown herein, but are to be accorded the widest scope consistent with this disclosure, the principles and the novel features disclosed herein. Additionally, a person having ordinary skill in the art will readily appreciate, the terms “upper” and “lower” are sometimes used for ease of describing the figures, and indicate relative positions corresponding to the orientation of the figure on a properly oriented page, and may not reflect the proper orientation of, e.g., a MEMS display element, including for example, a DMS display element as implemented.

Certain features that are described in this specification in the context of separate implementations also can be implemented in combination in a single implementation. Conversely, various features that are described in the context of a single implementation also can be implemented in multiple implementations separately or in any suitable subcombination. Moreover, although features may be described above as acting in certain combinations and even initially claimed as such, one or more features from a claimed combination can in some cases be excised from the combination, and the claimed combination may be directed to a subcombination or variation of a sub combination.

Similarly, while operations are depicted in the drawings in a particular order, a person having ordinary skill in the art will readily recognize that such operations need not be performed in the particular order shown or in sequential order, or that all illustrated operations be performed, to achieve desirable results. Further, the drawings may schematically depict one more example processes in the form of a flow diagram. However, other operations that are not depicted can be incorporated in the example processes that are schematically illustrated. For example, one or more additional operations can be performed before, after, simultaneously, or between any of the illustrated operations. In certain circumstances, multitasking and parallel processing may be advantageous. Moreover, the separation of various system components in the implementations described above should not be understood as requiring such separation in all implementations, and it should be understood that the described program components and systems can generally be integrated together in a single software product or packaged into multiple software products. Additionally, other implementations are within the scope of the following claims. In some cases, the actions recited in the claims can be performed in a different order and still achieve desirable results.

What is claimed is:

1. A microelectromechanical system (MEMS) device, comprising
a first electrode,
a second electrode adjacent the first electrode and defining a gap between the first and the second electrode and being capable of moving across the gap and toward the first electrode in response to a voltage difference between the first and the second electrode, and
a beam positioned away from the gap between the first and second electrode and being capable of deflecting in response to the second electrode moving toward the first electrode and thereby apply a force that opposes movement of the second electrode toward the first electrode.

2. A MEMS device of claim 1, further including an element extending from the second electrode and arranged to contact the beam as the second electrode moves toward the first electrode.

3. A MEMS device of claim 2, wherein the element extending from the second electrode includes a shutter.

4. A MEMS device of claim 2, wherein the beam further comprises a beam electrode and the element further comprises an element electrode capable of moving toward the beam electrode responsive to a voltage difference between the beam electrode and the element electrode.

5. A MEMS device of 1, wherein the beam has a first and second end and the first end attaches to an anchor and the second end is free to move.

6. A MEMS device of claim 1, wherein the beam has an accurate shape.

7. A MEMS device of claim 1, wherein the beam comprises an elastic material for elastically deflecting to store energy for driving the second electrode away from the first electrode.

8. A MEMS device of claim 1, wherein the beam deflects in accord with a spring force and the spring force is selected to prevent the second electrode from contacting the first electrode.

9. A MEMS device of claim 4, wherein the second electrode and the beam electrode are electrically connected to be at a substantially same voltage.

10. A MEMS device of claim 4, wherein the first electrode and the beam electrode are electrically connected to be at a substantially same voltage.

11. A MEMS device of claim 4, further comprising a controller for applying a first voltage difference between the first electrode and the second electrode and for applying a second different voltage difference between the beam electrode and the second electrode.

12. A MEMS device of claim 1, wherein the beam includes an element to limit deflection of the beam to prevent the second electrode from moving into contact with the first electrode.

13. A MEMS device of claim 1, further comprising:
a display;
a processor that is configured to communicate with the display, the processor being configured to process image data; and
a memory device that is configured to communicate with the processor.

14. The device of claim 13, further comprising:
a driver circuit configured to send at least one signal to the display; and
a controller configured to send at least a portion of the image data to the driver circuit.

15. The device of claim 13, further comprising:
an image source module configured to send the image data to the processor, wherein the image source module comprises at least one of a receiver, transceiver, and transmitter.

16. The device of claim 13, further comprising:
an input device configured to receive input data and to communicate the input data to the processor.

17. A method for manufacturing a microelectromechanical system (MEMS) device, comprising
providing an electrode pair having a first electrode and a second electrode adjacent the first electrode to define a gap between the first and the second electrode, and arranging the second electrode to be capable of moving across the gap and toward the first electrode in response to a voltage difference between the first and the second electrode, and
providing a beam positioned away from the gap and being capable of deflecting in response to the second electrode moving toward the first electrode to apply a force that opposes movement of the second electrode toward the first electrode.

18. The method of claim 17, wherein arranging the second electrode includes coupling the second electrode to a spring formed on a substrate and being capable of deflecting to allow the second electrode to move across the gap.

19. The method of claim 17, further including providing an element for extending from the second electrode and arranged to contact the beam as the second electrode moves toward the first electrode.

20. The method of claim 19, further comprising
forming a beam electrode on the beam, and
forming an element electrode on the element.

21. The method of claim 17, further comprising
forming an anchor on a substrate and securing an end of the beam to the anchor.

22. The method of claim 21, further comprising
forming a different end of the beam as an arm suspended over the substrate.

23. The method of claim 17, further comprising
forming the beam in an arcuate shape.

24. The method of claim 17, further comprising forming the beam of an elastic material for having the beam elastically deflect to store energy for driving the second electrode away from the first electrode.

25. The method of claim 24, further comprising selecting a width of the beam to provide a spring force selected to prevent the second electrode from contacting the first electrode.

26. The method of claim 17, further comprising forming an electrical interconnect between the second electrode and the beam electrode.

27. The method of claim 20, further comprising forming an electrical interconnect between the first electrode and the beam electrode.

28. The method of claim 20, further comprising providing a controller for applying a first voltage difference between the first electrode and the second electrode and for applying a second different voltage difference between the beam electrode and the second electrode.

29. The method of claim 17 further comprising
forming an element proximate the beam to limit deflection of the beam to prevent the second electrode from moving into contact with the first electrode.
